(19) United States
(12) Patent Application Publication
(10) Pub. No.: US 2025/0212698 A1
(43) Pub. Date: Jun. 26, 2025

(54) SEMICONDUCTOR-SUPERCONDUCTOR HYBRID STRUCTURE

(71) Applicant: Microsoft Technology Licensing, LLC, Redmond, WA (US)

(72) Inventors: Geoffrey C. GARDNER, West Lafayette, IN (US); Georg Wolfgang WINKLER, Santa Barbara, CA (US); Samuel Moses Langford TEICHER, Goleta, CA (US); Léo BOURDET, Delft, Zuid-Holland (NL); Fabiano CORSETTI, Copenhagen (DK); Andrey ANTIPOV, Santa Barbara, CA (US); Sergei GRONIN, West Lafayette, IN (US); Tyler LINDEMANN, West Lafayette, IN (US); Michael James MANFRA, West Lafayette, IN (US)

(21) Appl. No.: 18/612,475

(22) Filed: Mar. 21, 2024

Related U.S. Application Data
(60) Provisional application No. 63/613,511, filed on Dec. 21, 2023.

(51) Int. Cl. H10N 60/10; H10N 60/01

(52) U.S. Cl. CPC H10N 60/10; H10N 60/01

(57) ABSTRACT

The disclosure relates to a semiconductor-superconductor hybrid structure, which includes a substrate, a buffer region having a superlattice sub-region over the substrate and a graded lattice sub-region over the superlattice sub-region, an active region over the buffer region, a superconductor over the active region consisting of one or more patterned nanowires, and a cap layer encapsulating the superconductor and top surface portions of the active region not covered by the superconductor. The active region covers an entire top surface of the buffer region, is configured to quantum confine electrons, and has a top barrier layer configured to tune coupling between the superconductor and the active region to a desired value. The superlattice sub-region is configured to prevent impurity diffusion and crystalline defects propagating from the substrate to the active region, while the graded lattice sub-region is configured to provide a lattice constant transition between the substrate and the active region.

### RELATED APPLICATIONS

This application claims the benefit of provisional patent application Ser. No. 63/613,511, filed Dec. 21, 2023, the disclosure of which is hereby incorporated herein by reference in its entirety.

### FIELD OF THE DISCLOSURE

The present disclosure relates to a semiconductor-superconductor hybrid structure and methods for manufacturing the same.

### BACKGROUND

Many superconductor semiconductor hybrid devices for topological quantum computing rely on coupling between a semiconductor portion and a superconductor portion in a semiconductor-superconductor hybrid structure to provide material characteristics that are suitable for quantum operations. In one type of quantum device, the semiconductor portion provides patterned nanowires that are selectively grown on a substrate, while the superconductor portion is formed over and partially covers the patterned nanowires. Typically, the substrate, on which the semiconductor nanowires are grown, is often an insulating material. As such, there is often a large difference in the crystal lattice constant of the substrate and the nanowires to be grown. This crystal lattice mismatch causes crystalline defects in the nanowires during growth such as dislocations and stacking faults. The crystalline defects can penetrate the nanowires and in turn decrease the performance of the resulting nanowires. In addition, the patterned nanowires provided by the semiconductor portions cannot accommodate device operation needs in terms of device geometry, gate placement or fine tuning of the coupling with uniform barrier over the wire.

In light of the above, there is a need for improved semiconductor-superconductor hybrid structures for providing quantum computing devices.

### SUMMARY

The disclosure relates to a semiconductor-superconductor hybrid structure and methods for manufacturing the same. The disclosed semiconductor-superconductor hybrid structure includes a substrate, a buffer region having a superlattice sub-region over the substrate and a graded lattice sub-region over the superlattice sub-region, an active region over the graded lattice sub-region, and a superconductor over the active region. Herein, the active region is configured to quantum confine electrons, and covers an entire top surface of the buffer region. The superlattice sub-region of the buffer region is configured to prevent impurity diffusion and crystalline defects propagating from the substrate to the active region, while the graded lattice sub-region of the buffer region is configured to provide a lattice constant transition between the substrate and the active region. The superconductor over the active region consists of one or more patterned nanowires.

In one embodiment of the semiconductor-superconductor hybrid structure, the superlattice sub-region includes a number of repeats of a combination of a first superlattice layer and a second superlattice layer, the first superlattice layer and the second superlattice layer being formed of different materials. The graded lattice sub-region includes a number of discrete step layers, each of which is formed of a different material with a different lattice constant.

In one embodiment of the semiconductor-superconductor hybrid structure, the active region includes a back barrier layer over the graded lattice sub-region, a quantum well layer over the back barrier layer, and a top barrier layer over the quantum well layer. The superconductor is over the top barrier layer. Herein, bandgaps of the back barrier layer and the top barrier layer are higher than a bandgap of the quantum well layer, such that the bottom barrier and the top barrier layer are configured to confine electrons within the quantum well layer.

In one embodiment of the semiconductor-superconductor hybrid structure, the graded lattice sub-region is configured to provide an exponentially graded lattice constant between a lattice constant of the substrate and a lattice constant of the back barrier layer within the active region from a bottom surface of the graded lattice sub-region over the substrate and a top surface of the graded lattice sub-region on which the active region is provided.

In one embodiment of the semiconductor-superconductor hybrid structure, the graded lattice sub-region is configured to provide a complete lattice transition between a lattice constant of the substrate and a lattice constant of the back barrier layer within the active region from a bottom surface of the graded lattice sub-region over the substrate and a top surface of the graded lattice sub-region on which the active region is provided.

In one embodiment of the semiconductor-superconductor hybrid structure, the graded lattice sub-region is configured to provide a partial lattice transition between a lattice constant of the substrate and a lattice constant of the back barrier layer within the active region from a bottom surface of the graded lattice sub-region over the substrate and a top surface of the graded lattice sub-region on which the active region is provided.

In one embodiment of the semiconductor-superconductor hybrid structure, the substrate is formed of indium phosphide (InP) doped with iron (Fe). The lattice-match layer is formed of indium (In) aluminum (Al) arsenide (As) with 52% In and 48% Al (In_{0.52}Al_{0.48}As). The first superlattice layer is formed of indium (In) gallium (Ga) arsenide (As) with 58% In and 42% Ga (In_{0.58}Ga_{0.42}As), and the second superlattice layer is formed of indium (In) aluminum (Al) arsenide (As) with 47% In and 53% Al (In_{0.47}Al_{0.53}As). The graded lattice sub-region is formed of In_{(1-y)}Al_{y}As, where y decreases from 48% to 15.5% over a thickness of the graded lattice sub-region. Each discrete step layer has a different percentage of Al to achieve a different lattice constant. The back barrier layer is formed of indium (In) aluminum (Al) arsenide (As) with 84.5% In and 15.5% Al (In_{0.845}Al_{0.155}As). The quantum well layer is formed of indium arsenide (InAs). The top barrier layer is formed of In₍₁₋ₓ₎AlₓAs, where x is a fixed value between 6% and 15%. The superconductor is formed of Al. Herein, the top barrier layer is configured to tune electron coupling between the active region and the superconductor to a desired value.

In one embodiment of the semiconductor-superconductor hybrid structure, x is a fixed value between 10% and 13%, and the top barrier layer has a thickness between 4 nm and 8 nm.

In one embodiment of the semiconductor-superconductor hybrid structure, the top barrier layer is formed of In_{0.88}Al_{0.12}AS.

In one embodiment of the semiconductor-superconductor hybrid structure, each of the first superlattice layer and the second superlattice layer has a thickness between 2.5 nm and 10 nm. The graded lattice sub-region has a total thickness between 500 nm and 5000 nm and the number of discrete step layers includes 25-50 discrete step layers. The back barrier layer has a thickness between 10 nm and 50 nm, the quantum well layer has a thickness between 6 nm and 12 nm, and the top barrier layer has a thickness between 3 nm and 13 nm.

In one embodiment of the semiconductor-superconductor hybrid structure, the superlattice sub-region includes at least five repeats of the combination of the first superlattice layer and the second superlattice layer.

In one embodiment of the semiconductor-superconductor hybrid structure, each of the discrete step layers has an identical thickness between 20 nm and 100 nm.

In one embodiment of the semiconductor-superconductor hybrid structure, the discrete step layers include 25 discrete step layers, and each of the discrete step layers has an identical thickness of 50 nm.

In one embodiment of the semiconductor-superconductor hybrid structure, each of the one or more patterned nanowires of the superconductor has a width between 50 nm and 150 nm, a thickness between 3 nm and 10 nm, and a length between 2 μm and 7 μm.

In one embodiment of the semiconductor-superconductor hybrid structure, the buffer region further includes a lattice-match layer that is coupled between the substrate and the superlattice sub-region, and has substantially a same lattice constant as the substrate.

In one embodiment of the semiconductor-superconductor hybrid structure, the lattice-match layer is formed of a same material as a first step layer of the discrete step layers within the graded lattice sub-region, where the first step layer is adjacent to the superlattice sub-region. The lattice-match layer has a thickness between 50 nm and 250 nm.

According to one embodiment, the semiconductor-superconductor hybrid structure further includes a cap layer encapsulating the superconductor and portions of a top surface of the active region that are not covered by the superconductor.

In one embodiment of the semiconductor-superconductor hybrid structure, the cap layer is formed of aluminum oxide (Al₂O₃) and has a thickness between 2 nm and 10 nm.

According to one embodiment, a method for manufacturing a semiconductor-superconductor hybrid structure starts with providing a substrate. Next, a buffer region is formed over the substrate. The buffer region includes a superlattice sub-region over the substrate and a graded lattice sub-region over the superlattice sub-region. An active region, which is configured to quantum confine electrons, is then formed over the graded lattice sub-region of the buffer region. Herein, the superlattice sub-region is configured to prevent impurity diffusion and crystalline defects propagating from the substrate to the active region. The graded lattice sub-region is configured to provide a lattice constant transition between the substrate and the active region. The active region covers an entire top surface of the buffer region. After the active region is formed, a superconductor, which consists of one or more patterned nanowires, is formed over the active region. Lastly, a cap layer is formed to encapsulate the superconductor and portions of a top surface of the active region that are not covered by the superconductor.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a semiconductor-superconductor hybrid structure according to one embodiment of the present disclosure.

FIG. 2 illustrates a superlattice sub-region within the semiconductor-superconductor hybrid structure shown in FIG. 1.

FIGS. 3A and 3B illustrate a graded sub-region within the semiconductor-superconductor hybrid structure shown in FIG. 1.

FIG. 4 is a flow chart illustrating a method for manufacturing the semiconductor-superconductor hybrid structure according to one embodiment of the present disclosure.

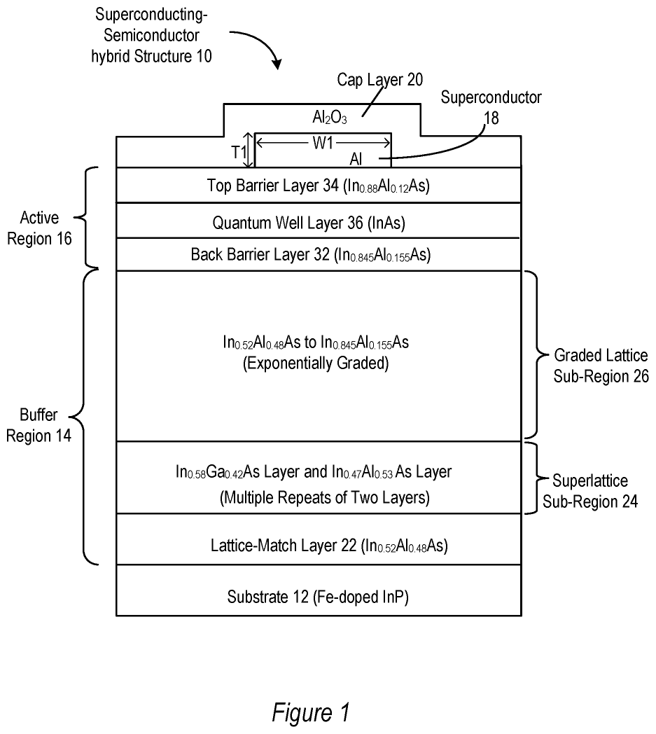

It will be understood that for clear illustrations, FIGS. 1-4 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

FIG. 1 shows a semiconductor-superconductor hybrid structure 10 according to one embodiment of the present disclosure. The semiconductor-superconductor hybrid structure 10 includes a substrate 12, a buffer region 14 on the substrate 12, an active region 16 on the buffer region 14, a superconductor 18 on the active region 16, and a cap layer 20 covering the superconductor 18 and the active region 16. Typically, the substrate 12 is an insulator or a semi-insulator, while the active region 16, which is configured to quantum confine charge carriers (e.g., electrons), must comprise conductive semiconductors to be functional. Since conductive semiconductors and insulators/semi-insulators generally have very different lattice constants, direct contact between the active region 16 and the substrate 12 will result in a high lattice mismatch between the active region 16 and the substrate 12. To solve this problem, the buffer region 14 is provided between the substrate 12 and the active region 16. In addition, the active region 16 (formed of conductive semiconductors) does not provide patterned wires but fully covers a top surface of the buffer region 14, while the superconductor 18 consists of one or more patterned wires and is formed directly over a top surface of the active region 16.

In one exemplary embodiment, the substrate 12 may be semi-insulating and is formed of indium phosphide (InP) doped with iron (Fe). The substrate 12 may have a thickness between 50 μm and 1000 μm, e.g., a thickness of 350 μm. The buffer region 14 vertically between the substrate 12 and the active region 16 is configured not only to provide a lattice constant transition between the substrate 12 and the active region 16, but also to provide electrically insulating buffer and prevent impurity diffusion and crystalline defects propagating from the substrate 12 to the active region 16, thereby to maintain the integrity/purity of the active region 16 in the final product.

In detail, the buffer region 14 includes a lattice-match layer 22 over the substrate 12, a superlattice sub-region 24 over the substrate lattice-match layer 22, and a graded lattice sub-region 26 over the superlattice sub-region 24. The lattice-match layer 22 may be formed of indium (In) aluminum (Al) arsenide (As) with 52% In and 48% Al (In_{0.52}Al_{0.48}As) and epitaxy grown directly on the substrate 12. The lattice-match layer 22 has a thickness between 50 nm and 250 nm (e.g., 100 nm) and has substantially the same lattice constant as the substrate 12.

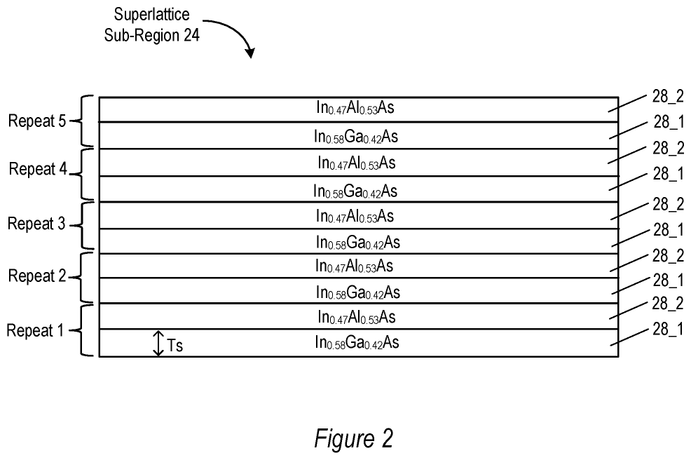

The superlattice sub-region 24 has a periodic configuration of superlattice layers of two (i.e., a first superlattice layer 28-1 and a second superlattice layer 28-2), as illustrated in FIG. 2. The superlattice sub-region 24 is configured to prevent impurity diffusion and crystalline defects propagating from the substrate 12 to the active region 16. For the purpose of this illustration, the superlattice sub-region 24 includes five repeats of a combination of the first superlattice layer 28-1 and the second superlattice layer 28-2 (i.e., the superlattice sub-region 24 includes five first superlattice layers 28-1 and five second superlattice layers 28-2, which are alternated with the first superlattice layers 28-1). In different applications, the superlattice sub-region 24 may include more than five repeats of the combination of the first superlattice layer 28-1 and the second superlattice layer 28-2. One of the first superlattice layers 28-1 is epitaxy grown directly on the lattice-match layer 22 and one of the second superlattice layers 28-2 is located at a top of the superlattice sub-region 24 (i.e., a top surface of the superlattice sub-region 24 is a top surface of one second superlattice layer 28-2). Each first superlattice layer 28-1 may be formed of indium (In) gallium (Ga) arsenide (As) with 58% In and 42% Ga (In_{0.58}Ga_{0.42}As), and each second superlattice layer 28-2 may be formed of indium (In) aluminum (Al) arsenide (As) with 47% In and 53% Al (In_{0.47}Al_{0.53}As). Each superlattice layer 28-1/28-2 may have a thickness Ts between 2.5 nm and 10 nm (e.g. each superlattice layer 28-1/28-2 has a thickness of 2.5 nm). The thickness Ts of each superlattice layer 28-1/28-2 may be the same or different.

The graded lattice sub-region 26 has a graded lattice constant that is between the lattice constant of the substrate 12 and a lattice constant of the active region 16 (e.g., a lattice constant of a back barrier of the active region 16, more details are described in the following paragraphs). The graded lattice sub-region 26 may provide a transition between the lattice constant of the substrate 12 and the lattice constant of the active region 16 over a thickness of the graded lattice sub-region 26 such that the transition occurs from a bottom surface of the graded lattice sub-region 26 adjacent to the substrate 12 to a top surface of the graded lattice sub-region 26 on which the active region 16 is provided. The graded lattice sub-region 26 may provide a partial transition between the lattice constant of the substrate 12 and the lattice constant of the active region 16 or a complete transition between the lattice constant of the substrate 12 and the lattice constant of the active region 16.

In one exemplary embodiment, the graded lattice sub-region 26 is formed of In_{(1-y)}Al_{y}As, where y decreases from 48% to 15.5% over the thickness of the graded lattice sub-region 26 (e.g., starting at In_{0.52}Al_{0.48}As, same as the lattice-match layer 22 having a lattice constant matched to the substrate 12, and ending in In_{0.845}Al_{0.155}As). Herein, the graded lattice sub-region 26 may be configured to provide an exponentially graded lattice constant from the substrate 12 to the active region 16. In other words, the lattice constant variation within the graded lattice sub-region 26 gradually decreases from a bottom portion of the graded lattice sub-region 26 close to the substrate 12 to a top portion of the graded lattice sub-region 26 adjacent to the active region 16. As such, the lattice variation about the active region 16 is small enough to be neglectable. The graded lattice sub-region 26 provides a much better lattice match for the active region 16 than the substrate 12. Accordingly, by adding the graded lattice sub-region 26 between the substrate 12 and the active region 16, defects such as misfit dislocations, slip planes, and stacking faults can be reduced or eliminated.

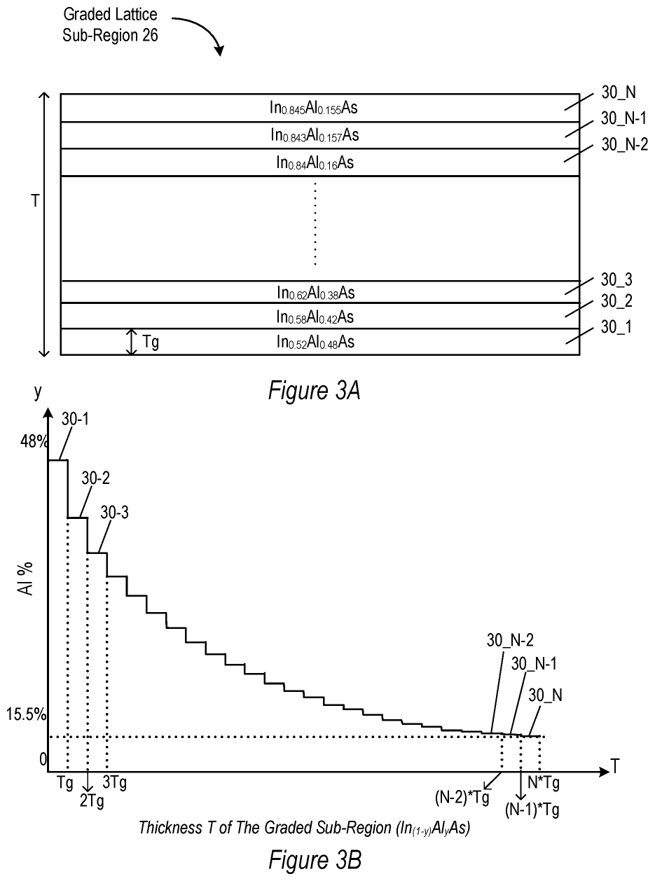

As illustrated in FIGS. 3A and 3B, the graded lattice sub-region 26 includes N discrete step layers 30, each of which has different percentages of In and Al in In_{(1-y)}Al_{y}As to achieve a different lattice constant, so as to provide the transition (e.g., at least partial transition) in lattice constant from the lattice constant of the substrate 12 to the lattice constant of the active region 16. A first step layer 30_1 is formed of In_{0.52}Al_{0.48}As, epitaxy grown directly on the superlattice sub-region 24 (e.g., directly on one second superlattice layer 28-2 of the superlattice sub-region 24) and close to the substrate 12, while a Nth step layer 30_N is formed of In_{0.845}Al_{0.155}As and adjacent to the active region 16. In various embodiments, the graded lattice sub-region 26 may have a total thickness T between 500 nm and 5000 nm, with 25-50 discrete step layers 30. Each step layer 30 may have an identical thickness Tg between 20 nm and 100 nm. For a non-limited example, the graded lattice sub-region 26 has a thickness of 1250 nm and includes 25 discrete step layers 30, each of which has a 50 nm thickness. The Al percentage (also the In percentage) within the graded lattice sub-region 26 varies exponentially along the thickness of the graded lattice sub-region 26. In particular, the Al percentage decreases faster/more in discrete step layers 30 closer to the substrate 12 (e.g., the first step layer 30_1, a second step layer 30_2, and a third step layer 30_3) than discrete step layers 30 closer to the active region 16 (e.g., a (N−2)th step layer 30_N−2, a (N−1)th step layer 30_N−1, and the Nth step layer 30_N).

Referring back to FIG. 1, the active region 16 with a thickness between 20 nm and 75 nm includes a back barrier layer 32, a top barrier layer 34, and a quantum well layer 36 vertically sandwiched between the back barrier layer 32 and the top barrier layer 34. The back barrier layer 32 is epitaxy grown directly on the graded lattice sub-region 26 and may have the same lattice constant as the Nth step layer 30_N of the graded lattice sub-region 26. When the Nth step layer 30_N is formed of In_{0.845}Al_{0.155}As, the back barrier layer 32 may also be formed of In_{0.845}Al_{0.155}As with a thickness between 10 nm and 50 nm (e.g., 25 nm). The quantum well layer 36 is epitaxy grown directly on the back barrier layer 32 and may be formed of indium arsenide (InAs) with a thickness between 6 nm and 12 nm, or between 7 nm and 11 nm (e.g., 9.1 nm). The top barrier layer 34 is epitaxy grown directly on the quantum well layer 36 and may be formed of In₍₁₋ₓ₎AlₓAs, where x might be a value between 10% and 13%, or between 6% and 15%. The top barrier layer 34 may have a thickness between 3 nm and 13 nm, or between 4 nm and 8 nm (e.g., the top barrier layer 34 is In_{0.88}Al_{0.12}As with a 6 nm thickness).

It is noticed that the active region 16 (e.g., each of the back barrier layer 32, the top barrier layer 34, and the quantum well layer 36) does not provide any nanowire shape. Instead, the active region 16 fully covers the top surface of the graded lattice sub-region 26. In order to enable the active region 16 transmitting the electrons consistently and uniformly, the top surface of the graded lattice sub-region 26 (i.e. the top surface of the Nth step layer 30_N of the graded lattice sub-region 26), on which the active region 16 is provided, should have a sharp well-defined interface. The “sharp well-defined surface” as referred to herein and hereafter is a surface with a vertical roughness below 20 Å, or desirably below 5 Å. Herein, bandgaps of the back barrier layer 32 (e.g., In_{0.845}Al_{0.155}As) and the top barrier layer 34 (e.g., In_{0.88}Al_{0.12}As) are higher than a bandgap of the quantum well layer 36 (e.g., InAs), thus the bottom barrier 32 and the top barrier layer 34 are configured to confine electrons within the quantum well layer 36.

The superconductor 18, which is formed of Al, is directly deposited on a top surface of the active region 16 (i.e., a top surface of the top barrier layer 34 of the active region 16). For the purpose of this illustration, the superconductor 18 includes a patterned wire with a width W1 between 50 nm and 150 nm, a thickness T1 between 3 nm and 10 nm, and a length (extending orthogonally into the drawing sheet, not shown) between 2 μm and 7 μm. The patterned wire provided by the superconductor 18 has a nanowire configuration. In different applications, the superconductor 18 includes two or more patterned wires, each of which has a nanowire configuration. The electron coupling between the superconductor 18 and the active region 16, which affects quantum operating performance, can be regulated/modulated by careful selection of the top barrier layer 34 (e.g., material and thickness of the top barrier layer 34). The top barrier layer 34 is configured to tune the electron coupling between semiconductor (e.g., the active region 16) and superconductor (e.g., the superconductor 18) to a desired/ideal value. Since the active region 16 fully covers the top surface of the graded lattice sub-region 26 but is not required to provide any nanowire configuration, the top barrier layer 34 enables uniform coupling to the superconductor 18 and has more flexibility in thickness tuning.

Portions of the top surface of the active region 16 are not covered by the superconductor 18. In addition, the superconductor hybrid structure 10 further includes the cap layer 20 that encapsulates the superconductor 18 and covers the uncovered portions of the top surface of the active region 16 through the superconductor 18. The cap layer 20 is configured to protect the superconductor 18 from oxidation and to provide a dielectric over the active region 16 and the superconductor 18. The cap layer 20 may be formed of aluminum oxide (Al₂O₃) with a thickness between 2 nm and 10 nm, or between 2 nm and 5 nm.

The materials and thicknesses described for the substrate 12, the buffer region 14 (i.e., the lattice-match layer 22, the superlattice sub-region 24, and the graded lattice sub-region 26), the active region 16 (i.e., the back barrier layer 32, the quantum well layer 36, and the top barrier layer 34), the superconductor 18, and the cap layer 20 are examples, but not limited thereto. The materials and thicknesses within the semiconductor-superconductor hybrid structure 10 need to be carefully selected so as to achieve desired characteristics, such as the integrity/purity of the active region 16.

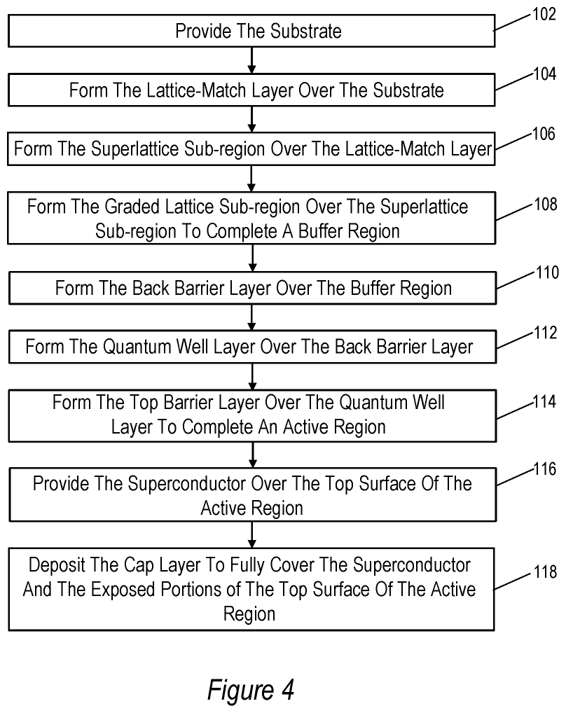

FIG. 4 is a flow diagram illustrating a method for manufacturing the semiconductor-superconductor hybrid structure 10 according to some embodiments of the present disclosure. Although the exemplary steps are illustrated in a series, the exemplary steps are not necessarily order dependent. Some steps may be done in a different order than that presented. Further, processes within the scope of this disclosure may include fewer or more steps than those illustrated in FIG. 4.

The method begins by providing the substrate 12 (step 102). The lattice-match layer 22 is then formed over the substrate 12 (step 104). The lattice-match layer 22 may be formed by any suitable manufacturing process, such as molecular-beam epitaxy (MBE), chemical beam epitaxy (CBE), chemical vapor deposition (CVD), or metal organic chemical vapor deposition (MOCVD). Next, the superlattice sub-region 24 is formed over the lattice-match layer 22 (step 106). As discussed above, the superlattice sub-region 24 includes multiple first superlattice layers 28-1 and multiple second superlattice layers 28-2, which are alternated with the first superlattice layers 28-1, and thus forming the superlattice sub-region 24 includes periodically forming multiple repeats of the combination of the first superlattice layer 28-1 and the second superlattice layer 28-2. Each superlattice layer 28-1/28-2 may be formed by any suitable manufacturing process, such as MBE, CBE, CVD, or MOCVD. The graded lattice sub-region 26 is formed over the superlattice sub-region 24 to complete the buffer region 14 (step 108). As discussed above, the graded lattice sub-region 26 includes multiple discrete step layers 30, each of which is formed of a different material (e.g., different element percentages) having different properties (e.g., a different lattice constant). As such, forming the graded lattice sub-region 26 includes forming the discrete step layers 30 one on top of the other. Each discrete step layer 30 may be formed by any suitable manufacturing process, such as MBE, CBE, CVD, or MOCVD. The buffer region 14 is provided as a blanket over an entire top surface of the substrate 12.

After the buffer region 14 is completed, the active region 16 is formed over the buffer region 14. In order to enable the active region 16 transmitting the electrons consistently and uniformly, the top surface of the buffer region 14 (i.e., the top surface of the graded lattice sub-region 26, or the top surface of the Nth step layer 30_N of the graded lattice sub-region 26), on which the active region 16 is provided, should have a sharp well-defined interface. The back barrier layer 32 is formed over the top surface of the buffer region 14 (i.e., the top surface of the graded lattice sub-region 26, step 110), the quantum well layer 36 is formed over a top surface of the back barrier layer 32 (step 112), and the top barrier layer 34 is formed over the top surface of the quantum well layer 36 to complete the active region 16 (step 114). Each of the back barrier layer 32, the quantum well layer 36, and the top barrier layer 34 may be formed by any suitable manufacturing process, such as MBE, CBE, CVD, or MOCVD. Further as discussed above, the back barrier layer 32 is provided as a blanket layer over the entire top surface of the buffer region 14, the quantum well layer 36 is provided as a blanket layer over the entire top surface of the back barrier layer 32, and the top barrier layer 34 is provided as a blanket layer over the entire top surface of the quantum well layer 36. As such, the active region 14 fully covers the entire top surface of the buffer region 14.

Next, the superconductor 18 is provided over the top surface of the active region 16 (step 116). Herein, the superconductor 18 includes one or more patterned wires, each of which has a nanowire configuration. The top barrier layer 34 of the active region 16 enables uniform coupling to the superconductor 18. Since the superconductor 18 consists of the one or more patterned nanowires, portions of the top surface of the active region 16 (i.e., portions of the top surface of the top barrier layer 34) are exposed through the superconductor 18. The superconductor 18 may be provided by an iterative deposition process. After the superconductor 18 is provided, the cap layer 20 is deposited to fully cover the superconductor 18 and the exposed portions of the top surface of the active region 16 (step 118). The cap layer 20 is configured to protect the superconductor 18 from oxidation and to provide a dielectric over the active region 16 and the superconductor 18.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A semiconductor-superconductor hybrid structure comprising:
a substrate;
a buffer region including a superlattice sub-region over the substrate and a graded lattice sub-region over the superlattice sub-region;
an active region over the graded lattice sub-region and configured to quantum confine electrons, wherein:
the superlattice sub-region is configured to prevent impurity diffusion and crystalline defects propagating from the substrate to the active region;
the graded lattice sub-region is configured to provide a lattice constant transition between the substrate and the active region; and
the active region covers an entire top surface of the buffer region; and
a superconductor over the active region and consisting of one or more patterned nanowires.

2. The semiconductor-superconductor hybrid structure of claim 1, wherein:
the superlattice sub-region includes a plurality of repeats of a combination of a first superlattice layer and a second superlattice layer, wherein the first superlattice layer and the second superlattice layer are formed of different materials; and
the graded lattice sub-region includes a plurality of discrete step layers, each of which is formed of a different material with a different lattice constant.

3. The semiconductor-superconductor hybrid structure of claim 2, wherein:
the active region includes a back barrier layer over the graded lattice sub-region, a quantum well layer over the back barrier layer, and a top barrier layer over the quantum well layer;
the superconductor is over the top barrier layer; and
bandgaps of the back barrier layer and the top barrier layer are higher than a bandgap of the quantum well layer, such that the bottom barrier and the top barrier layer are configured to confine electrons within the quantum well layer.

4. The semiconductor-superconductor hybrid structure of claim 3, wherein the graded lattice sub-region is configured to provide an exponentially graded lattice constant between a lattice constant of the substrate and a lattice constant of the back barrier layer within the active region from a bottom surface of the graded lattice sub-region over the substrate and a top surface of the graded lattice sub-region on which the active region is provided.

5. The semiconductor-superconductor hybrid structure of claim 3, wherein the graded lattice sub-region is configured to provide a complete lattice transition between a lattice constant of the substrate and a lattice constant of the back barrier layer within the active region from a bottom surface of the graded lattice sub-region over the substrate and a top surface of the graded lattice sub-region on which the active region is provided.

6. The semiconductor-superconductor hybrid structure of claim 3, wherein the graded lattice sub-region is configured to provide a partial lattice transition between a lattice constant of the substrate and a lattice constant of the back barrier layer within the active region from a bottom surface of the graded lattice sub-region over the substrate and a top surface of the graded lattice sub-region on which the active region is provided.

7. The semiconductor-superconductor hybrid structure of claim 3, wherein:
the substrate is formed of indium phosphide (InP) doped with iron (Fe);
the first superlattice layer is formed of indium (In) gallium (Ga) arsenide (As) with 58% In and 42% Ga (In_{0.58}Ga_{0.42}As), and the second superlattice layer is formed of indium (In) aluminum (Al) arsenide (As) with 47% In and 53% Al (In_{0.47}Al_{0.53}As);
the graded lattice sub-region is formed of In_{(1-y)}Al_{y}As, wherein y decreases from 48% to 15.5% over a thickness of the graded lattice sub-region;
each of the plurality of discrete step layers has a different percentage of Al and a different percentage of In to achieve a different lattice constant;
the back barrier layer is formed of In_{0.845}Al_{0.155}As;
the quantum well layer is formed of indium arsenide (InAs);
the top barrier layer is formed of In₍₁₋ₓ₎AlₓAs, wherein x is a fixed value between 6% and 15%; and
the superconductor is formed of AI, wherein the top barrier layer is configured to tune electron coupling between the active region and the superconductor to a desired value.

8. The semiconductor-superconductor hybrid structure of claim 7, wherein x is a fixed value between 10% and 13%, and the top barrier layer has a thickness between 4 nm and 8 nm.

9. The semiconductor-superconductor hybrid structure of claim 8, wherein the top barrier layer is formed of In_{0.88}Al_{0.12}As.

10. The semiconductor-superconductor hybrid structure of claim 7, wherein:
each of the first superlattice layer and the second superlattice layer has a thickness between 2.5 nm and 10 nm;
the graded lattice sub-region has a total thickness between 500 nm and 5000 nm and the plurality of discrete step layers includes 25-50 discrete step layers;
the back barrier layer has a thickness between 10 nm and 50 nm;
the quantum well layer has a thickness between 6 nm and 12 nm; and
the top barrier layer has a thickness between 3 nm and 13 nm.

11. The semiconductor-superconductor hybrid structure of claim 10, wherein the superlattice sub-region includes at least five repeats of the combination of the first superlattice layer and the second superlattice layer.

12. The semiconductor-superconductor hybrid structure of claim 10, wherein each of the plurality of discrete step layers has an identical thickness between 20 nm and 100 nm.

13. The semiconductor-superconductor hybrid structure of claim 12, wherein the plurality of discrete step layers includes 25 discrete step layers, and each of the plurality of discrete step layers has an identical thickness of 50 nm.

14. The semiconductor-superconductor hybrid structure of claim 7, wherein each of the one or more patterned nanowires of the superconductor has a width between 50 nm and 150 nm, a thickness between 3 nm and 10 nm, and a length between 2 μm and 7 μm.

15. The semiconductor-superconductor hybrid structure of claim 2, wherein the buffer region further includes a lattice-match layer that is coupled between the substrate and the superlattice sub-region, and has substantially a same lattice constant as the substrate.

16. The semiconductor-superconductor hybrid structure of claim 15, wherein:
the lattice-match layer is formed of a same material as a first step layer of the plurality of discrete step layers within the graded lattice sub-region, wherein the first step layer is adjacent to the superlattice sub-region; and
the lattice-match layer has a thickness between 50 nm and 250 nm.

17. The semiconductor-superconductor hybrid structure of claim 1 further comprising a cap layer encapsulating the superconductor and portions of a top surface of the active region that are not covered by the superconductor.

18. The semiconductor-superconductor hybrid structure of claim 17 wherein the cap layer is formed of aluminum oxide (Al₂O₃) and has a thickness between 2 nm and 10 nm.

19. A method for manufacturing a semiconductor-superconductor hybrid structure comprising:
providing a substrate;
forming a buffer region over the substrate, wherein the buffer region includes a superlattice sub-region over the substrate and a graded lattice sub-region over the superlattice sub-region;
forming an active region over the graded lattice sub-region, wherein:
the active region is configured to quantum confine electrons;
the superlattice sub-region is configured to prevent impurity diffusion and crystalline defects propagating from the substrate to the active region;
the graded lattice sub-region is configured to provide a lattice constant transition between the substrate and the active region; and
the active region covers an entire top surface of the buffer region;
forming a superconductor over the active region, wherein the superconductor consists of one or more patterned nanowires; and
forming a cap layer to encapsulate the superconductor and portions of a top surface of the active region that are not covered by the superconductor.

20. The method of claim 19, wherein:
the superlattice sub-region includes a plurality of repeats of a combination of a first superlattice layer and a second superlattice layer, wherein the first superlattice layer and the second superlattice layer are formed of different materials;
the graded lattice sub-region includes a plurality of discrete step layers, each of which is formed of a different material with a different lattice constant;
the active region includes a back barrier layer over the graded lattice sub-region, a quantum well layer over the back barrier layer, and a top barrier layer over the quantum well layer;
the superconductor is over the top barrier layer; and
bandgaps of the back barrier layer and the top barrier layer are higher than a bandgap of the quantum well layer, such that the bottom barrier and the top barrier layer are configured to confine electrons within the quantum well layer.

21. The method of claim 20, wherein:
the substrate is formed of indium phosphide (InP) doped with iron (Fe);
the first superlattice layer is formed of indium (In) gallium (Ga) arsenide (As) with 58% In and 42% Ga (In_{0.58}Ga_{0.42}As), and the second superlattice layer is formed of indium (In) aluminum (Al) arsenide (As) with 47% In and 53% Al (In_{0.47}Al_{0.53}As);
the graded lattice sub-region is formed of In_{(1-y)}Al_{y}As, wherein y decreases from 48% to 15.5% over a thickness of the graded lattice sub-region;
each of the plurality of discrete step layers has a different percentage of Al and a different percentage of In to achieve a different lattice constant;
the back barrier layer is formed of In_{0.845}Al_{0.155}As;
the quantum well layer is formed of indium arsenide (InAs);
the top barrier layer is formed of In₍₁₋ₓ₎AlₓAs, wherein x is a fixed value between 6% and 15%;
the superconductor is formed of Al, wherein the top barrier layer is configured to tune electron coupling between the active region and the superconductor to a desired value; and
the cap layer is formed of aluminum oxide (Al₂O₃).
